(19) United States
(12) Patent Application Publication
(10) Pub. No.: US 2021/0076531 A1
(43) Pub. Date: Mar. 11, 2021

(54) IMMERSION COOLING APPARATUS

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(21) Appl. No.: 16/572,629

(22) Filed: Sep. 17, 2019

(30) Foreign Application Priority Data
Sep. 6, 2019 (CN) 201910843209.7

(51) Int. Cl. H05K 7/20

(52) U.S. Cl. CPC H05K 7/203

(57) ABSTRACT

An immersion cooling apparatus includes a heat-generating member, a chamber and a plurality of metal tubes. The chamber has a plurality of upper steam-discharging outlets. The chamber stores a cooling solution and contains the heat-generating member to make the heat-generating member immersed in the cooling solution. The plurality of metal tubes is communicated with the plurality of the upper steam-discharging outlets respectively. Each metal tube extends upward from the upper steam-discharging outlet to guide steam generated by the cooling solution when the cooling solution absorbs heat of the heat-generating member to leave the chamber through the upper steam-discharging outlets and then enter the metal tubes. When the metal tubes cool the steam into liquid, the liquid flows downward along each metal tube and then flows into the cooling solution through the plurality of upper steam-discharging outlets.

### BACKGROUND OF THE INVENTION

### 1. Field of the Invention

The present invention relates to an immersion cooling apparatus, and more specifically, to an immersion cooling apparatus having a plurality of metal tubes extending upward from upper steam-discharging outlets of a chamber.

### 2. Description of the Prior Art

In general, an immersion cooling apparatus immerses heat-generating members (e.g. servers, hard disk drive arrays) into a cooling solution stored in a cooling chamber. In this cooling design, the cooling solution can absorb heat energy of the heat-generating member to generate steam, and then the steam can be cooled into liquid by a fan device. Finally, the cooled liquid can be transmitted back to the cooling chamber by a pump, so as to achieve the heat-dissipating purpose. In practical application, the immersion cooling apparatus needs to adopt a fanless cooling design for specific application (e.g. vehicle heat dissipation). In brief, the fanless cooling design involves guiding the steam to a heat-dissipating device via a heat-dissipating tube for cooling the steam into the liquid and then returning the cooled liquid back to the cooling chamber. However, since there is no design applied to the heat-dissipating tube for automatically returning the liquid, it causes a high flow resistance in the heat-dissipating tube, so as to considerably reduce the heat-dissipating effect and liquid-returning efficiency of the immersion cooling apparatus.

### SUMMARY OF THE INVENTION

The present invention provides an immersion cooling apparatus. The immersion cooling apparatus includes a heat-generating member, a chamber, and a plurality of metal tubes. The chamber has a plurality of upper steam-discharging outlets. The chamber stores a cooling solution and contains the heat-generating member to make the heat-generating member immersed in the cooling solution. The plurality of metal tubes is communicated with the plurality of the upper steam-discharging outlets respectively. Each metal tube extends upward from the corresponding upper steam-discharging outlet to guide steam generated by the cooling solution when the cooling solution absorbs heat of the heat-generating member to leave the chamber through the plurality of upper steam-discharging outlets and then enter the plurality of metal tubes. When the plurality of metal tubes cools the steam into liquid, the liquid flows downward along each metal tube and then flows into the cooling solution through the plurality of upper steam-discharging outlets.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of an immersion cooling apparatus according to an embodiment of the present invention.

FIG. 2 is a partial enlarged cross-sectional diagram of a metal tube in FIG. 1 being communicated with an upper steam-discharging outlet of a chamber.

### DETAILED DESCRIPTION

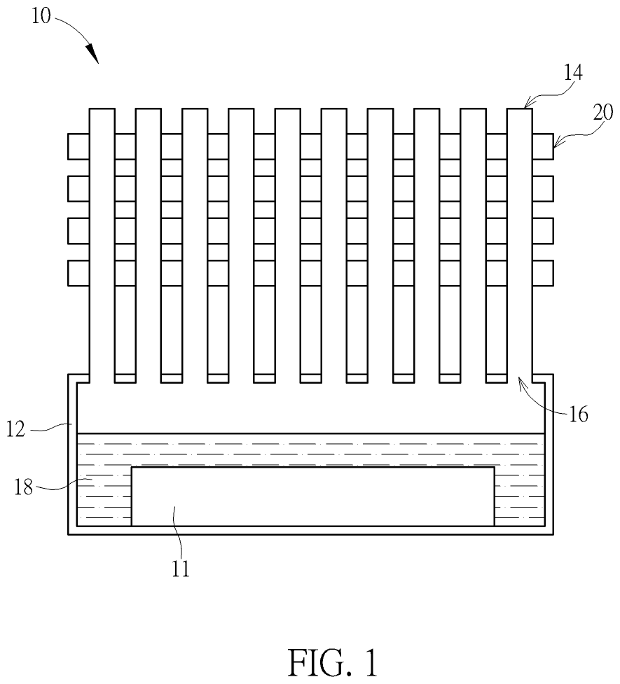

Please refer to FIG. 1, which is a cross-sectional diagram of an immersion cooling apparatus 10 according to an embodiment of the present invention. The immersion cooling apparatus 10 is used for cooling a heat-generating member 11 (e.g. blade servers or hard disk drive arrays). As shown in FIG. 1, the immersion cooling apparatus 10 includes the heat-generating member 11, a chamber 12, and a plurality of metal tubes 14. The chamber 12 could be a solution storage chamber commonly applied to an immersion cooling apparatus (the chamber design is commonly seen in the prior art and the related description is omitted herein) and has a plurality of upper steam-discharging outlets 16. The chamber 12 is used for storing a cooling solution 18 and containing the heat-generating member 11, so that the heat-generating member 11 can be immersed in the cooling solution 18. The cooling solution 18 could be an inert dielectric solution (e.g. mineral oil or silicone oil).

As shown in FIG. 1, the plurality of metal tubes 14 is communicated with the plurality of upper steam-discharging outlets respectively. Each metal tube 14 extends upward from the corresponding upper steam-discharging outlet 16, so that steam generated by the cooling solution 18 when the cooling solution 18 absorbs heat energy of the heat-generating member 11 can leave the chamber 12 through the plurality of upper steam-discharging outlets 16 and then enter the plurality of metal tubes 14. In this embodiment, each metal tube 14 could extend vertically from the corresponding upper steam-discharging outlet 16, but not limited thereto, meaning that the present invention could adopt the design that each metal tube extends upwardly and obliquely from the corresponding upper steam-discharging outlet in another embodiment and the related description could be reasoned by analogy according to FIG. 1 and omitted herein.

Furthermore, the immersion cooling apparatus 10 could adopt a heat-dissipating design that the metal tubes have a heat-dissipating device mounted thereon. For example, as shown in FIG. 1, the immersion cooling apparatus 10 could further include a heat-dissipating device 20. In this embodiment, the heat-dissipating device 20 could preferably be a heat-dissipating fin structure (but not limited thereto), and the plurality of metal tubes 14 is disposed through the heat-dissipating fin structure, so as to make the heat-dissipating fin structure efficiently absorb the heat energy of the steam flowing into the plurality of metal tubes 14 to cool the steam into the liquid quickly. To be noted, via the design that the plurality of metal tubes 14 extends upward from the chamber 12, the immersion cooling apparatus 10 could further extend the metal tubes 14 having the heat-dissipating device 20 mounted thereon to a position where the temperature is lower (e.g. outdoor environment) or the airflow velocity is higher (e.g. the metal tube 14 could extend outside a vehicle for heat dissipation via the airflow while the vehicle is moving), so as to greatly increase the heat-dissipating efficiency of the immersion cooling apparatus 10.

In such a manner, when the heat-generating member 11 is working to generate the heat energy, the steam generated by the cooling solution 18 when the cooling solution 18 absorbs the heat energy leaves the chamber 12 through the plurality of steam-discharging outlets 16, and then flows into the plurality of metal tubes 14. During the aforesaid process, the plurality of metal tubes 14 can cool the steam from the upper steam-discharging outlets 16 into the liquid via high thermal conductivity of each metal tube 14 and the heat-dissipating device 20 contacting the external environment outside the immersion cooling apparatus 10. At this time, as shown in FIG. 1, since the extending direction of each metal tube 14 is parallel to the gravity direction, the cooled liquid can flow into the cooling solution 18 along the metal tubes 14 quickly due to gravity and then continue to cool the heat-generating member 11. In such a manner, the present invention can greatly improve the heat-dissipating effect and the liquid-returning efficiency of the immersion cooling apparatus 10.

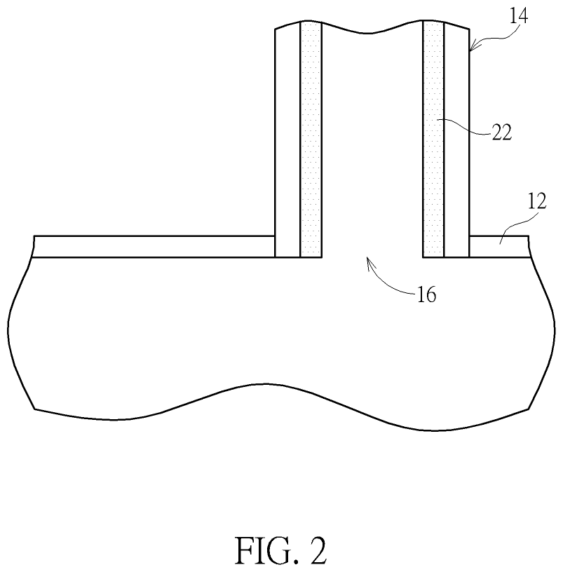

It should be mentioned that the present invention could further adopt the capillary structural design. For example, please refer to FIG. 2, which is a partial enlarged cross-sectional diagram of the metal tube 14 in FIG. 1 being communicated with the upper steam-discharging outlet 16 of the chamber 12. As shown in FIG. 2, in this embodiment, the immersion cooling apparatus 10 could further include a capillary structure 22. The capillary structure 22 is disposed in the metal tube 14 (the related description for the capillary structural design and the capillary principle is commonly seen in the prior art and omitted herein). Accordingly, when the metal tube 14 cools the steam from the upper steam-discharging outlet 16 into the liquid via high thermal conductivity of the metal tube 14 and the heat-dissipating device 20 contacting the external environment outside the immersion cooling apparatus 10, the liquid flows into the cooling solution 18 in the chamber 12 along the metal tube 14 more quickly via guidance of the capillary structure 22, so as to reduce the flow resistance in the metal tube 14 for further improving the liquid-returning efficiency of the metal tube 14 and the heat-dissipating performance of the immersion cooling apparatus 10.

Those skilled in the art will readily observe that numerous modifications and alterations of the device and method may be made while retaining the teachings of the invention. Accordingly, the above disclosure should be construed as limited only by the metes and bounds of the appended claims.

1. An immersion cooling apparatus comprising:
a heat-generating member;
a chamber having a plurality of upper steam-discharging outlets, the chamber storing a cooling solution and containing the heat-generating member to make the heat-generating member immersed in the cooling solution; and
a plurality of metal tubes communicated with the plurality of the upper steam-discharging outlets respectively, each metal tube extending upward from the corresponding upper steam-discharging outlet to guide steam generated by the cooling solution when the cooling solution absorbs heat of the heat-generating member to leave the chamber through the plurality of upper steam-discharging outlets and then enter the plurality of metal tubes; and
a heat-dissipating device disposed on the plurality of metal tubes for absorbing the heat of the steam flowing into the plurality of metal tubes to cool the steam into the liquid;
wherein when the plurality of metal tubes cools the steam into liquid, the liquid flows downward along each metal tube and then flows into the cooling solution through the plurality of upper steam-discharging outlets.

2. The immersion cooling apparatus of claim 1, wherein each metal tube extends vertically from the upper steam-discharging outlet.

3. (canceled)

4. The immersion cooling apparatus of claim 1,
wherein the heat-dissipating device is a heat-dissipating fin structure, and the plurality of metal tubes is disposed through the heat-dissipating fin structure, so as to make the heat-dissipating fin structure absorb the heat energy of the steam flowing into the plurality of metal tubes to cool the steam into the liquid.

5. The immersion cooling apparatus of claim 1 further comprising:
a capillary structure disposed in the plurality of metal tubes, the capillary structure guiding the liquid to flow downward along each metal tube and then flow into the cooling solution through the plurality of upper steam-discharging outlets.
